(19) United States
(12) Patent Application Publication
(10) Pub. No.: US 2026/0115837 A1
(43) Pub. Date: Apr. 30, 2026

(54) LASER PROCESSING APPARATUS AND LASER PROCESSING METHOD

(71) Applicant: DISCO CORPORATION, Tokyo (JP)

(72) Inventor: Haruna YANO, Tokyo (JP)

(21) Appl. No.: 19/355,586

(22) Filed: Oct. 10, 2025

(30) Foreign Application Priority Data
Oct. 28, 2024 (JP) 2024-188783

(51) Int. Cl. B23K 26/361; B23K 26/03; B23K 26/06; B23K 26/08; B23K 26/402; B23K 103/00; G01N 23/2055; H01L 21/02

(52) U.S. Cl. CPC B23K 26/361; B23K 26/03; B23K 26/0665; B23K 26/0823; B23K 26/083; B23K 26/402; G01N 23/2055; B23K 2103/56; H10P 90/128

(57) ABSTRACT

A laser processing apparatus includes a holding unit having a holding surface holding a workpiece, a beam condenser focusing a laser beam, a position adjusting unit adjusting a positional relation between the holding unit and a focused spot of the laser beam, a first rotation mechanism rotating the holding unit with a first rotational axis as a center, a second rotation mechanism rotating the holding unit or the beam condenser with a second rotational axis as a center, a crystal orientation information acquisition unit acquiring crystal orientation information for identifying a crystal orientation of the workpiece, and a controller. The controller is capable of applying the laser beam to the workpiece from the side surface side in a state in which the beam condenser faces a side surface of the workpiece and a position of the focused spot relative to the workpiece is adjusted according to the crystal orientation.

### BACKGROUND OF THE INVENTION

### Field of the Invention

The present invention relates to a laser processing apparatus and a laser processing method by which laser processing is performed on a workpiece having a crystal structure.

### Description of the Related Art

In a manufacturing process of device chips, a wafer having devices formed in a plurality of respective regions demarcated by a grid of a plurality of streets (dividing lines) is used. By dividing this wafer along the streets into individual pieces, device chips including the respective devices are manufactured. Such device chips are incorporated in various types of electronic equipment such as mobile phones and personal computers.

A wafer to be used for manufacturing device chips is formed by processing an ingot with a circular column shape. Specifically, by slicing a single-crystal ingot, a wafer having a crystal structure and a predetermined thickness is separated from the ingot. Then, the wafer thus separated from the ingot (an as-sliced wafer or an as-cut wafer) is subjected to such processing as chamfering processing which removes a corner portion present at an outer peripheral portion of the wafer (see Japanese Patent Laid-open No. 2019-212761).

### SUMMARY OF THE INVENTION

When a workpiece having the crystal structure, such as the wafer described above, is to be processed, a processing condition may be set according to a crystal orientation of the workpiece. In view of this, the workpiece having the crystal structure has a mark for identifying the crystal orientation of the workpiece provided thereon. For example, a cutout portion (a notch, an orientation flat, a mirror surface, or the like) indicating the crystal orientation is formed at an outer peripheral portion of the workpiece. This allows the crystal orientation of the workpiece to be recognized quickly, and the handling (transfer, holding, processing, and the like) according to the crystal orientation of the workpiece becomes easy.

The mark indicating the crystal orientation of the workpiece is formed by processing the workpiece by a processing apparatus such as a cutting apparatus or a laser processing apparatus. However, when a dedicated processing apparatus for formation of the mark is used, the number of steps and costs increase, so that the processing efficiency of the workpiece lowers. For example, in a case in which chamfering processing of the workpiece and processing of forming the mark in the workpiece are performed in separate processing apparatuses, two types of processing apparatuses need to be prepared and operated, and a transfer work for the workpiece between the processing apparatuses is also needed.

The present invention is made in view of such problems, and it is an object of the present invention to provide a laser processing apparatus and a laser processing method by which a plurality of types of processing can be performed on a workpiece in a simple way at low cost.

In accordance with an aspect of the present invention, there is provided a laser processing apparatus which applies a laser beam to a workpiece having a crystal structure to perform laser processing on the workpiece. The laser processing apparatus includes a holding unit including a holding surface for holding the workpiece having a first surface, a second surface, and a side surface that is connected to the first surface and the second surface, a laser oscillator which emits the laser beam, a beam condenser for focusing the laser beam emitted from the laser oscillator, a position adjusting unit which adjusts a positional relation between the holding unit and a focused spot of the laser beam, a first rotation mechanism which rotates the holding unit with a first rotational axis crossing the holding surface as a center, a second rotation mechanism which rotates the holding unit or the beam condenser with a second rotational axis crossing a direction parallel to the first rotational axis as a center, a crystal orientation information acquisition unit which acquires crystal orientation information for identifying a crystal orientation of the workpiece held on the holding unit, and a controller. The controller applies the laser beam to the workpiece from a side of the side surface in a state in which the beam condenser faces the side surface of the workpiece and a position of the focused spot relative to the workpiece is adjusted according to the crystal orientation of the workpiece identified by the crystal orientation information, by controlling the position adjusting unit, the first rotation mechanism, and the second rotation mechanism.

In accordance with another aspect of the present invention, there is provided a laser processing apparatus which applies a laser beam to a workpiece having a crystal structure to perform laser processing on the workpiece. The laser processing apparatus includes a holding unit including a holding surface for holding the workpiece having a first surface, a second surface, and a side surface that is connected to the first surface and the second surface, a laser oscillator which emits the laser beam, a beam condenser for focusing the laser beam emitted from the laser oscillator, a position adjusting unit which adjusts a positional relation between the holding unit and a focused spot of the laser beam, a first rotation mechanism which rotates the holding unit with a first rotational axis crossing the holding surface as a center, a second rotation mechanism which rotates the holding unit or the beam condenser with a second rotational axis crossing a direction parallel to the first rotational axis as a center, a crystal orientation information acquisition unit which acquires crystal orientation information for identifying a crystal orientation of the workpiece held on the holding unit, and a controller. The controller applies the laser beam to the workpiece from a side of the first surface or the second surface in a state in which the beam condenser faces the first surface or the second surface of the workpiece and a position of the focused spot relative to the workpiece is adjusted according to the crystal orientation of the workpiece identified by the crystal orientation information, by controlling the position adjusting unit, the first rotation mechanism, and the second rotation mechanism.

Note that, preferably, the controller switches between a state in which the beam condenser faces the side surface of the workpiece and a state in which the beam condenser faces the first surface or the second surface of the workpiece, by controlling the second rotation mechanism. In addition, preferably, the crystal orientation information acquisition unit detects a diffraction pattern detected by X-rays applied to the workpiece. More preferably, the laser processing apparatus further includes a workpiece information acquisition unit which acquires one of or both information regarding a shape of the workpiece and information regarding surface characteristics of the workpiece.

In accordance with a further aspect of the present invention, there is provided a laser processing method including holding a workpiece with a crystal structure having a first surface, a second surface, and a side surface connected to the first surface and the second surface on a holding surface of a holding unit, acquiring crystal orientation information for identifying a crystal orientation of the workpiece, adjusting a relative position and orientation between the holding unit and a beam condenser in such a manner that the beam condenser focusing a laser beam faces the side surface of the workpiece held on the holding unit, processing an outer peripheral portion of the workpiece into a predetermined shape by rotating the holding unit with a rotational axis crossing the holding surface as a center, while the laser beam is being applied to the workpiece held on the holding unit from the beam condenser that is caused to face the side surface of the workpiece, and forming a mark indicating a crystal orientation of the workpiece in the workpiece by adjusting a position of the focused spot of the laser beam relative to the workpiece, according to the crystal orientation of the workpiece identified by the crystal orientation information, and applying the laser beam to the workpiece held on the holding unit from the beam condenser that is caused to face the side surface of the workpiece.

In accordance with a still further aspect of the present invention, there is provided a laser processing method including holding a workpiece with a crystal structure having a first surface, a second surface, and a side surface connected to the first surface and the second surface on a holding surface of a holding unit, acquiring crystal orientation information for identifying a crystal orientation of the workpiece, adjusting a relative position and orientation between the holding unit and a beam condenser in such a manner that the beam condenser focusing a laser beam faces the side surface of the workpiece held on the holding unit, processing an outer peripheral portion of the workpiece into a predetermined shape by rotating the holding unit with a rotational axis crossing the holding surface as a center, while the laser beam is being applied to the workpiece held on the holding unit from the beam condenser that is caused to face the side surface of the workpiece, adjusting a relative position and orientation between the holding unit and the beam condenser in such a manner that the beam condenser faces the first surface or the second surface of the workpiece held on the holding unit, and forming a mark indicating a crystal orientation of the workpiece in the workpiece by adjusting a position of the focused spot of the laser beam relative to the workpiece, according to the crystal orientation of the workpiece identified by the crystal orientation information, and applying the laser beam to the workpiece held on the holding unit from the beam condenser that is caused to face the first surface or the second surface of the workpiece.

Note that, preferably, in the acquiring the crystal orientation information, a diffraction pattern of X-rays applied to the workpiece is detected. In addition, preferably, the mark is a plane formed at the outer peripheral portion of the workpiece, and one of or both a planar angle relative to the first surface or the second surface of the workpiece and a reflection direction of light applied to the plane is/are checked.

According to one aspect of the present invention, by causing the beam condenser focusing the laser beam to selectively face the side surface of the workpiece or the first surface or the second surface of the workpiece, the processing of forming the mark in the workpiece and the other types of processing can be performed by the same laser processing apparatus. Hence, a plurality of types of processing can be performed on the workpiece in a simple way at low cost.

The above and other objects, features and advantages of the present invention and the manner of realizing them will become more apparent, and the invention itself will best be understood from a study of the following description and appended claims with reference to the attached drawings showing preferred embodiments of the invention.

### BRIEF DESCRIPTION OF THE DRAWINGS

FIG. 1 is a perspective view depicting a workpiece;

FIG. 2 is a perspective view depicting a laser processing apparatus;

FIG. 3 is a schematic view depicting a laser beam applying unit;

FIG. 4 is a perspective view depicting the laser processing apparatus which holds the workpiece in a vertical direction;

FIG. 5 is a flow chart depicting a laser processing method;

FIG. 6 is a front view depicting the laser processing apparatus and the workpiece in a holding step;

FIG. 7 is a front view depicting the laser processing apparatus and the workpiece in a crystal orientation information acquisition step;

FIG. 8 is a front view depicting the laser processing apparatus and the workpiece in an adjusting step;

FIG. 9 is a front view depicting the laser processing apparatus and the workpiece in a first beam irradiation step;

FIG. 10 is a front view depicting an outer peripheral portion of the workpiece obtained after chamfering processing is performed;

FIG. 11 is a front view depicting the laser processing apparatus and the workpiece in a second beam irradiation step;

FIG. 12 is a side view depicting the workpiece and a laser beam in the second beam irradiation step;

FIG. 13A is a front view depicting part of the workpiece and a workpiece information acquisition unit when an angle of a mark is checked;

FIG. 13B is a front view depicting part of the workpiece and the workpiece information acquisition unit when a reflection direction of light applied to the mark is checked;

FIG. 14 is a flow chart depicting a modification example of the laser processing method;

FIG. 15 is a front view depicting the laser processing apparatus and the workpiece in a second adjusting step;

FIG. 16 is a front view depicting the laser processing apparatus and the workpiece in the second beam irradiation step; and

FIG. 17 is a plan view depicting the workpiece and the laser beam in the second beam irradiation step.

### DETAILED DESCRIPTION OF THE PREFERRED EMBODIMENTS

### First Embodiment

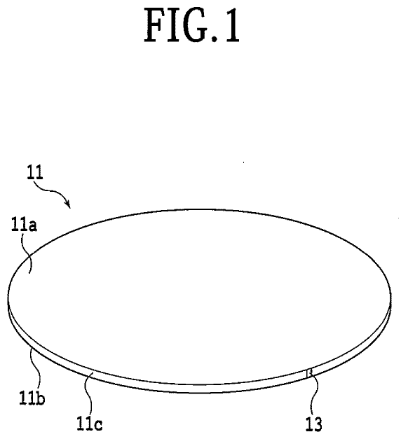

Hereinafter, embodiments according to aspects of the present invention will be described with reference to the attached drawings. First, a configuration example of a workpiece which can be processed by a laser processing apparatus or a laser processing method according to the present embodiment will be described. FIG. 1 is a perspective view depicting a workpiece 11.

The workpiece 11 is a plate-shaped member having a crystal structure and includes a first surface 11a and a second surface 11b, which are substantially parallel to each other, and a side surface (outer peripheral surface) 11c, which is connected to the first surface 11a and the second surface 11b. For example, the workpiece 11 is a disc-shaped wafer including a single-crystal silicon, gallium oxide, gallium nitride, lithium tantalate (LT), lithium niobate (LN), diamond, or the like.

The workpiece 11 is formed by slicing a crystalline ingot. Part of the ingot with a circular column shape is separated from the main body of the ingot, so that the workpiece 11 having a predetermined thickness is obtained. A material and a diameter of the ingot are selected according to a material and a diameter (6 inches, 8 inches, or the like) of the workpiece 11 to be formed.

The workpiece 11 has a mark (marking) 13 indicating the crystal orientation of the workpiece 11 provided thereon. For example, the mark 13 corresponds to a cutout portion that is formed at an outer peripheral portion of the workpiece 11, such as a notch, an orientation flat, or a mirror surface. In addition, the mark 13 may have a structure of a hole, a groove, a protrusion, or the like formed in the workpiece 11, or a differently-colored region which is colored in a color different from those of the other regions of the workpiece 11 by coloring, discoloring, or the like.

By way of example, a case in which the mark 13 is a mirror surface (flat surface) will be described. The side surface 11c of the workpiece 11 is formed in a circular ring shape, except for a region in which the mirror surface is present. Meanwhile, the mirror surface corresponds to a region of the side surface 11c of the workpiece 11 which is formed in a flat surface substantially vertical to the first surface 11a and the second surface 11b. Further, the position of the mirror surface is set in such a manner as to indicate the crystal orientation of the workpiece 11. For example, the position of the mirror surface is selected such that a straight line connecting the center of the workpiece 11 with the mirror surface becomes parallel or vertical to a predetermined crystal orientation of the workpiece 11.

The mirror surface can be detected by an optical sensor. For example, when light is applied along the side surface 11c of the workpiece 11 from a reflective optical sensor, a reflection direction of the light is different between a case in which light is applied to the mirror surface and a case in which light is applied to the other regions, resulting in a change in an amount of received light of the optical sensor. Hence, according to the amount of the received light of the optical sensor, the position of the mirror surface can be identified. Consequently, according to the position of the mirror surface, the crystal orientation of the workpiece 11 can be recognized.

Dimensions of the mirror surface are not limited to any particular numerical values as long as the optical sensor can detect the mirror surface. For example, in a case in which the diameter of the workpiece 11 is 200 mm, a width of the mirror surface (a length of the mirror surface in a tangent direction of the workpiece 11) can be set to be substantially 10 mm. Accordingly, in a case in which the mirror surface is formed as the mark 13, compared to a case in which the notch or the orientation flat is formed, the dimensions of the mark 13 are greatly reduced. As a result, a large usable region (a region in which devices are to be formed, a process margin, or the like) can be reserved in the workpiece 11, and production efficiency of a product using the workpiece 11 is improved.

In addition, processing other than formation of the mark 13 is also performed on the workpiece 11. For example, chamfering processing for processing the outer peripheral portion of the workpiece 11 to a predetermined shape is performed on the workpiece 11. The chamfering processing is processing of removing a corner portion which is formed at a connection portion between the first surface 11a and the side surface 11c of the workpiece 11 and a corner portion which is formed at a connection portion between the second surface 11b and the side surface 11c of the workpiece 11. When the workpiece 11 is subjected to the chamfering processing, for example, the side surface 11c is shaped into a curved surface (arc shape) extending from the first surface 11a to the second surface 11b. In this case, the side surface 11c is in a state of being curved toward the outside of the workpiece 11 in the radial direction.

Note that, in a case in which the mirror surface described above is formed as the mark 13 in the workpiece 11 having the side surface 11c being shaped into a curved surface by the chamfering processing, the mirror surface is formed at an edge portion of the side surface 11c. For example, by removing substantially 0.5 mm of the material of the workpiece 11 with a diameter of 200 mm from the edge of the side surface 11c toward the center of the workpiece 11, the mirror surface of an elliptical shape having a major axis of substantially 10 mm can be formed.

For example, the workpiece 11 is demarcated in a plurality of rectangular regions by a grid of a plurality of crossing streets (dividing lines). In addition, respective devices such as integrated circuits (ICs), large scale integration (LSI) circuits, light emitting diodes (LEDs), and microelectromechanical system (MEMS) devices are formed in the plurality of regions divided along the streets on the first surface 11a side. Thereafter, by dividing the workpiece 11 along the streets into individual pieces, a plurality of device chips each including the device are obtained.

When the workpiece 11 is to be divided, the workpiece 11 is processed by various types of processing apparatuses. At this time, owing to the crystal structure of the workpiece 11, a processing feature may change. In this case, the orientation of the workpiece 11 is adjusted according to the position of the mark 13, and the workpiece 11 is processed under a condition taking the crystal orientation into account.

To carry out the chamfering processing and the formation of the mark 13 described above, a laser processing apparatus which performs laser processing on the workpiece 11 can be used. Further, the chamfering processing and the formation of the mark 13 are sequentially performed with the same laser processing apparatus, so that the number of steps and the costs required for processing of the workpiece 11 can be reduced. Hereinafter, a configuration example of the laser processing apparatus according to the present embodiment will be described.

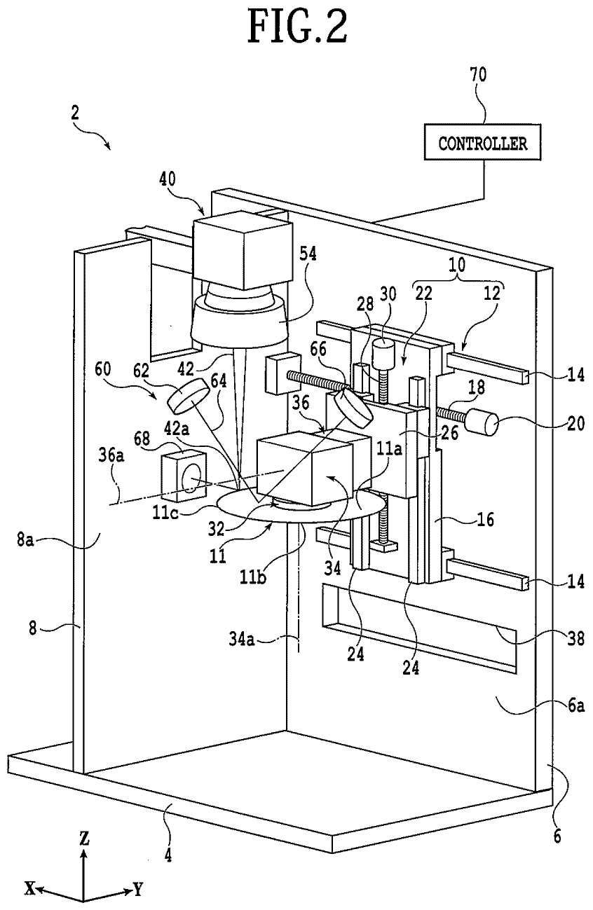

FIG. 2 is a perspective view depicting a laser processing apparatus 2. In FIG. 2, an X-axis direction (a first horizontal direction, or a left-right direction) and a Y-axis direction (a second horizontal direction, or a front-rear direction) are perpendicular to each other. In addition, a Z-axis direction (an up-down direction, a height direction, or a vertical direction) is a direction vertical to the X-axis direction and the Y-axis direction.

The laser processing apparatus 2 includes a base 4 which supports components included in the laser processing apparatus 2. For example, the base 4 is formed into a rectangular shape, and an upper surface of the base 4 forms a flat surface that is substantially parallel to a horizontal surface (XY plane). A back end portion of the base 4 and a side end portion thereof are provided with respective support structures 6 and 8 in a rectangular shape. A front surface 6a of the support structure 6 faces in a front direction and is disposed along an XZ plane. Meanwhile, a front surface 8a of the support structure 8 faces in a lateral direction and is disposed along a YZ plane. In other words, the front surface 6a of the support structure 6 and the front surface 8a of the support structure 8 are disposed to be substantially perpendicular to each other in plan view.

A position adjusting unit 10 is provided on the front surface 6a of the support structure 6. The position adjusting unit 10 is a mechanism which adjusts a positional relation between a holding unit 32 and a focused spot 42a of a laser beam 42 as described below, and, for example, includes a moving mechanism of a ball screw system. Specifically, the position adjusting unit 10 includes an X-axis moving unit (X-axis moving mechanism) 12 and a Z-axis moving unit (Z-axis moving mechanism) 22.

The X-axis moving unit 12 includes a pair of X-axis guide rails 14 disposed along the X-axis direction on the front surface 6a of the support structure 6. The pair of X-axis guide rails 14 have an X-axis moving plate 16 in a plate shape slidably attached thereto along the X-axis guide rails 14. An X-axis ball screw 18 is disposed between the pair of X-axis guide rails 14 along the X-axis direction. In addition, on a back surface (rear side) of the X-axis moving plate 16, a nut portion (not illustrated) is provided, and the X-axis ball screw 18 is screwed into this nut portion. Further, an X-axis pulse motor 20 which rotates the X-axis ball screw 18 is coupled with an end portion of the X-axis ball screw 18. When the X-axis pulse motor 20 rotates the X-axis ball screw 18, the X-axis moving plate 16 moves along the X-axis guide rails 14 in the X-axis direction.

The Z-axis moving unit 22 includes a pair of Z-axis guide rails 24 disposed along the Z-axis direction on the front surface (front side) of the X-axis moving plate 16. The pair of Z-axis guide rails 24 have a Z-axis moving plate 26 in a plate shape slidably attached thereto along the Z-axis guide rails 24. A Z-axis ball screw 28 is disposed between the pair of Z-axis guide rails 24 along the Z-axis direction. In addition, a nut portion (not illustrated) is provided on a back surface (rear side) of the Z-axis moving plate 26, and the Z-axis ball screw 28 is screwed into this nut portion. Further, a Z-axis pulse motor 30 which rotates the Z-axis ball screw 28 is coupled with an end portion of the Z-axis ball screw 28. When the Z-axis pulse motor 30 rotates the Z-axis ball screw 28, the Z-axis moving plate 26 moves along the Z-axis guide rails 24 in the Z-axis direction.

The position adjusting unit 10 described above is coupled with the holding unit 32 that holds the workpiece 11. The holding unit 32 is connected to a front surface of the Z-axis moving plate 26 through a first rotation mechanism 34 and a second rotation mechanism 36.

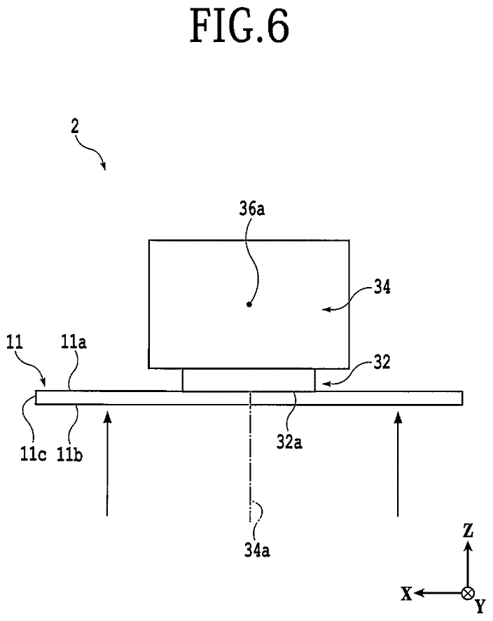

For example, the holding unit 32 includes a holding table (chuck table). A lower surface of the holding unit 32 is a flat surface substantially parallel to the horizontal surface (XY plane) and includes a circular holding surface 32a (see FIG. 6 and the like) for holding the workpiece 11. The holding surface 32a is connected with a suction source such as an ejector (not illustrated) through a flow channel (not illustrated), a valve (not illustrated), or the like, which is formed in the holding unit 32. When a suction force (negative pressure) of the suction source is applied to the holding surface 32a in a state in which the workpiece 11 is in contact with the holding surface 32a, the workpiece 11 is held under suction by the holding unit 32. However, the configuration of the holding unit 32 is not limited to any particular configuration as long as the holding unit 32 can hold the workpiece 11. For example, the holding unit 32 may include a plurality of suction pads for holding under suction the workpiece 11. In this case, a distal end surface (suction surface) of the suction pad which comes into contact with the workpiece 11 corresponds to the holding surface 32a.

The holding unit 32 has the first rotation mechanism 34 which rotates the holding unit 32 coupled therewith. The first rotation mechanism 34 includes a rotary drive source such as a motor and allows the holding unit 32 to be rotated 360° in both directions with a first rotational axis 34a crossing the holding surface 32a as a center. For example, the first rotational axis 34a is an axis passing through the center of the holding surface 32a and being perpendicular to the holding surface 32a and is disposed to be substantially parallel to the XZ plane direction.

The first rotation mechanism 34 has the second rotation mechanism 36 which rotates the holding unit 32 along with the first rotation mechanism 34 coupled therewith. The second rotation mechanism 36 includes a rotary drive source such as a motor and allows the holding unit 32 to be rotated 360° in both directions with the second rotational axis 36a crossing a direction parallel to the first rotational axis 34a as a center. For example, the second rotational axis 36a is set along a direction perpendicular to the first rotational axis 34a and is disposed substantially in parallel to the Y-axis direction.

The X-axis moving unit 12 moves the X-axis moving plate 16 along the X-axis direction, thereby moving the holding unit 32 along with the first rotation mechanism 34 and the second rotation mechanism 36 along the X-axis direction. In addition, the Z-axis moving unit 22 moves the Z-axis moving plate 26 along the Z-axis direction, thereby moving (lifting/lowering) the holding unit 32 along with the first rotation mechanism 34 and the second rotation mechanism 36 along the Z-axis direction. As a result, the workpiece 11 held on the holding unit 32 can be positioned at a desired position in the XZ plane. In addition, the first rotation mechanism 34 and the second rotation mechanism 36 are actuated, thereby allowing a rotation angle and the orientation of the workpiece 11 held on the holding unit 32 to be freely set.

Inside and/or outside the laser processing apparatus 2, a transfer unit (not illustrated) which transfers the workpiece 11 is provided. For example, a transfer mechanism such as a transfer robot is used as the transfer unit. In addition, a transfer port 38 for transferring the workpiece 11 is provided at a lower portion of the support structure 6 in such a manner as to penetrate the support structure 6. When the workpiece 11 is to be processed by the laser processing apparatus 2, the workpiece 11 held on the transfer unit is loaded into the laser processing apparatus 2 from the rear side to the front side of the support structure 6 through the transfer port 38 and held on the holding unit 32. Then, when the laser processing apparatus 2 finishes processing the workpiece 11, the workpiece 11 is again held on the transfer unit and unloaded from the laser processing apparatus 2 from the front side to the rear side of the support structure 6 through the transfer port 38.

A laser beam applying unit 40 which applies the laser beam 42 is provided on the front surface 8a side of the support structure 8. The laser beam 42 is applied from the laser beam applying unit 40 to the workpiece 11 held on the holding unit 32, thereby subjecting the workpiece 11 to laser processing.

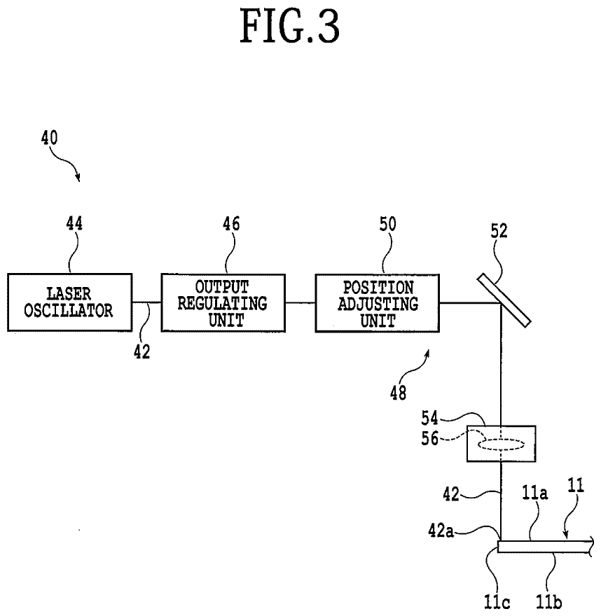

FIG. 3 is a schematic view depicting the laser beam applying unit 40. The laser beam applying unit 40 includes a laser oscillator 44, such as an yttrium aluminum garnet (YAG) laser, an yttrium orthovanadate (YVO₄) laser, or an yttrium lithium fluoride (YLF) laser, for emitting a pulsed laser beam 42, and an output regulating unit 46 such as an attenuator for regulating the output power of the laser beam 42 emitted from the laser oscillator 44. In addition, the laser beam applying unit 40 includes an optical system 48 for guiding the laser beam 42 to the workpiece 11 held on the holding unit 32 (see FIG. 2). The optical system 48 includes a plurality of optical elements and controls a direction of travel of the laser beam 42, a shape of the laser beam 42, a position of the focused spot of the laser beam 42, and the like.

Specifically, the optical system 48 includes a position adjusting unit 50 for adjusting a position to be irradiated with the laser beam 42 (the direction of travel of the laser beam, the direction of ray of light). The position adjusting unit 50 changes and adjusts the direction of travel of the laser beam 42 that is emitted from the laser oscillator 44 and that has its output power regulated by the output regulating unit 46. For example, the position adjusting unit 50 includes an acousto-optic deflector (AOD), an electro-optic deflector (EOD), a galvanoscanner, an optical MEMS, or the like. However, the position adjusting unit 50 is not limited to any particular configuration as long as it is able to adjust the direction of travel of the laser beam 42. In addition, the optical system 48 includes a mirror 52 for reflecting the laser beam 42 and a beam condenser 54 for focusing the laser beam 42. As the mirror 52, for example, a dielectric multilayered film mirror is used. The laser beam 42 emitted from the position adjusting unit 50 is reflected on a reflection surface of the mirror 52 and is applied to the beam condenser 54. The beam condenser 54 includes a focusing lens 56, such as an fθ lens, for focusing the laser beam 42 and applying the focused laser beam 42 onto the workpiece 11. The laser beam 42 applied to the beam condenser 54 is focused at a predetermined position by the focusing lens 56.

The various types of optical elements described above constitute the optical system 48. However, the optical elements included in the optical system 48 are not limited to any particular elements. For example, the optical system 48 may further include optical elements such as other mirrors and lenses, polygon mirrors, a polarizing beam splitter (PBS), a diffractive optical element (DOE), or a liquid crystal on silicon-spatial light modulator (LCOS-SLM).

As illustrated in FIG. 2, the beam condenser 54 of the laser beam applying unit 40 is set above the holding unit 32. Further, the laser beam 42 is applied from the beam condenser 54 to the workpiece 11 in a state in which the focused spot 42a of the laser beam 42 is positioned on the front surface of the workpiece 11 or the vicinity thereof, or inside the workpiece 11, and predetermined laser processing is performed on the workpiece 11.

Note that the positional relation between the holding unit 32 and the focused spot 42a of the laser beam 42 can be adjusted by the position adjusting unit 10 and/or the position adjusting unit 50 (see FIG. 3). Specifically, the position adjusting unit 10 moves the holding unit 32 along the X-axis direction and/or the Z-axis direction, so that the position of the holding unit 32 relative to the focused spot 42a can be changed. In addition, the position adjusting unit 50 (see FIG. 3) changes the direction of the laser beam 42 to be applied and the height position of the focused spot 42a, so that the position of the focused spot 42a relative to the holding unit 32 can be changed.

In addition, the laser processing apparatus 2 includes a crystal orientation information acquisition unit 60 which acquires information (crystal orientation information) for identifying the crystal orientation of the workpiece 11. Further, the laser processing apparatus 2 identifies the crystal orientation of the workpiece 11, according to the crystal orientation information acquired by the crystal orientation information acquisition unit 60. The crystal orientation of the workpiece 11 is used for determination of the position of the mark 13 to be formed in the workpiece 11 (see FIG. 1) in the later step.

For example, the crystal orientation information acquisition unit 60 includes an X-ray diffraction (XRD) apparatus for detecting a diffraction pattern of X-rays applied to the workpiece 11. Specifically, the crystal orientation information acquisition unit 60 includes an X-ray irradiator 62, which emits X-rays 64, and a detector 66, which detects a diffraction pattern of the X-rays 64. The X-ray irradiator 62 applies the X-rays 64 to the workpiece 11 held on the holding unit 32. When the X-rays 64 are applied to the workpiece 11, the X-rays 64 are scattered by crystals included in the workpiece 11, and a diffraction phenomenon of the X-rays 64 occurs. Then, the detector 66 receives the X-rays 64 and detects the diffraction pattern of the X-rays 64. The diffraction pattern of the X-rays 64 detected by the detector 66 corresponds to the crystal orientation information. Thereafter, the crystal orientation of the workpiece 11 is identified according to the diffraction pattern of the X-rays 64. For example, the crystal orientation information acquisition unit 60 includes a computing unit which identifies the crystal orientation of the workpiece 11 according to a ratio of the peak intensity of the diffraction pattern, or the like. However, computation for identifying the crystal orientation of the workpiece 11 may be carried out by a controller 70 described later.

Note that the function and the configuration of the crystal orientation information acquisition unit 60 are not limited to any particular function and configuration, as long as the crystal orientation information can be acquired. For example, when the workpiece 11 is processed by the laser beam 42 on trial, cracks occur in the workpiece 11. It has been confirmed that a developing direction of the cracks depends on the crystal orientation of the workpiece 11. In view of this, an imaging unit (camera) is used as the crystal orientation information acquisition unit 60, to image the workpiece 11 subjected to test processing, and accordingly, an image of the workpiece 11 having the cracks formed therein may be acquired. In this case, the image of the workpiece 11 is the crystal orientation information, and the crystal orientation of the workpiece 11 can be identified according to the developing direction of the cracks indicated in the image.

In addition, in the above description, an example in which the crystal orientation information acquisition unit 60 acquires the crystal orientation information in a state in which the workpiece 11 is held on the holding unit 32 has been described. However, there is no particular limitation on the timing of acquiring the crystal orientation information, and the crystal orientation information may be acquired before the workpiece 11 is held by the holding unit 32. For example, the crystal orientation information acquisition unit 60 may acquire the crystal orientation information, in a state in which the workpiece 11 is held by the transfer unit or another holding unit included in the laser processing apparatus 2. In addition, before the workpiece 11 is loaded into the laser processing apparatus 2, the crystal orientation information of the workpiece 11 may be acquired by an appropriate method in advance.

Moreover, the laser processing apparatus 2 includes a workpiece information acquisition unit 68 which can acquire information other than the crystal orientation of the workpiece 11. The workpiece information acquisition unit 68 is provided at such a position as to be able to acquire information on the workpiece 11 held on the holding unit 32. In FIG. 2, the workpiece information acquisition unit 68 is attached on the front surface 8a of the support structure 8 in such a manner as to be positioned below the beam condenser 54 of the laser beam applying unit 40.

For example, the workpiece information acquisition unit 68 is a sensor (inspection section) capable of acquiring one of or both information regarding the shape of the workpiece 11 and information regarding the surface characteristics of the workpiece 11. Specifically, the workpiece information acquisition unit 68 includes a camera, a photoelectric sensor (fiber sensor or the like), a displacement gage (contact type or non-contact type), a proximity sensor, or the like. Further, the workpiece information acquisition unit 68 detects the mark 13 formed in the workpiece 11 and measures information (size, shape, angle, or the like) regarding the shape of the mark 13 and information (surface roughness, specular reflectance, reflectance of light, or the like) regarding the surface characteristics of the mark 13. Hence, it is possible to check and evaluate whether or not the mark 13 is suitably formed in the workpiece 11.

In addition, the laser processing apparatus 2 includes a controller (a control unit, a control section, or a control device) 70 for controlling the laser processing apparatus 2. The controller 70 is connected to each of the components (the position adjusting unit 10, the holding unit 32, the first rotation mechanism 34, the second rotation mechanism 36, the laser beam applying unit 40, the crystal orientation information acquisition unit 60, the workpiece information acquisition unit 68, and the like) included in the laser processing apparatus 2. The controller 70 outputs a control signal to the components of the laser processing apparatus 2, thereby controlling actions of the components to operate the laser processing apparatus 2. For example, the controller 70 includes a computer. Specifically, the controller 70 includes a processing unit, which executes computation processing or the like required for control of the laser processing apparatus 2, and a storing unit, which stores various types of information (data, a program, or the like) to be used for control of the laser processing apparatus 2. The processing unit includes a processor such as a central processing unit (CPU). In addition, the storing unit includes a memory such as a read only memory (ROM) or a random access memory (RAM).

Moreover, the laser processing apparatus 2 may include a component for executing input/output of information. For example, the laser processing apparatus 2 further includes a display unit (a display section, or a display device) for displaying various types of information regarding the laser processing apparatus 2, and a notification unit (a notification section, or a notification device) for notifying an operator of information.

As the display unit, for example, a touch panel is used. In this case, an operation screen for inputting information to the laser processing apparatus 2 is displayed on the touch panel, and the operator can input information to the laser processing apparatus 2 by a touch operation on the touch panel. Specifically, the touch panel functions as an input unit (an input section, or an input device) for inputting various types of information to the laser processing apparatus 2 and is used as a user interface. However, the input unit may be an input device such as a mouse or a keyboard independently and separately provided from the display unit.

The notification unit is, for example, an indicator lamp, i.e., a warning lamp, which is continuously lit or blinks when the laser processing apparatus 2 malfunctions, indicating an error to the operator. However, the notification unit is not limited to any particular type. For example, the notification unit may alternatively be a speaker that gives information to the operator by way of sound or speech or a transmitter which transmits information outside the laser processing apparatus 2.

When the workpiece 11 is subjected to laser processing by the laser processing apparatus 2, first, the transfer unit (not illustrated) holds the workpiece 11 and loads it into the laser processing apparatus 2 through the transfer port 38. As a result, the workpiece 11 is held under suction on the holding unit 32.

Next, the position adjusting unit 10, the first rotation mechanism 34, the second rotation mechanism 36, and/or the position adjusting unit 50 (see FIG. 3) sets the rotation angle and the orientation of the workpiece 11, the positional relation between the workpiece 11 and the focused spot 42a of the laser beam 42, the irradiation direction of the laser beam 42, and the like. Subsequently, the laser beam 42 is applied to the workpiece 11 from the laser beam applying unit 40 under a predetermined irradiation condition. As a result, predetermined laser processing is performed on the workpiece 11.

In particular, in the present embodiment, the laser processing apparatus 2 performs processing for forming the mark 13 (see FIG. 1) in the workpiece 11 and other types of processing. Hence, the single laser processing apparatus 2 can sequentially perform a plurality of types of processing on the workpiece 11. As a result, the process of processing the workpiece 11 is simplified, and the cost is also reduced. More specifically, the laser processing apparatus 2 causes the controller 70 to control the second rotation mechanism 36 such that the holding unit 32 is rotated around the second rotational axis 36a, making it possible to freely set the orientation of the workpiece 11 held on the holding unit 32. Hence, it is possible to switch between a state in which the beam condenser 54 faces the first surface 11a or the second surface 11b of the workpiece 11 and a state in which the beam condenser 54 faces the side surface 11c of the workpiece 11. As a result, processing of applying the laser beam 42 to the workpiece 11 from the first surface 11a side or the second surface 11b side and processing of applying the laser beam 42 to the workpiece 11 from the side surface 11c side can selectively be performed.

FIG. 2 depicts the laser processing apparatus 2 which holds the workpiece 11 in the horizontal direction. When the second rotation mechanism 36 adjusts the orientation of the holding unit 32 (the rotation angle about the second rotational axis 36a) in such a manner that the holding surface 32a (see FIG. 6 and the like) is substantially parallel to the horizontal surface (XY plane), the workpiece 11 is held along the horizontal surface, and the first surface 11a side or the second surface 11b side of the workpiece 11 faces the beam condenser 54 of the laser beam applying unit 40. This makes it possible to perform laser processing of applying the laser beam 42 to the workpiece 11 from the first surface 11a side or the second surface 11b side thereof.

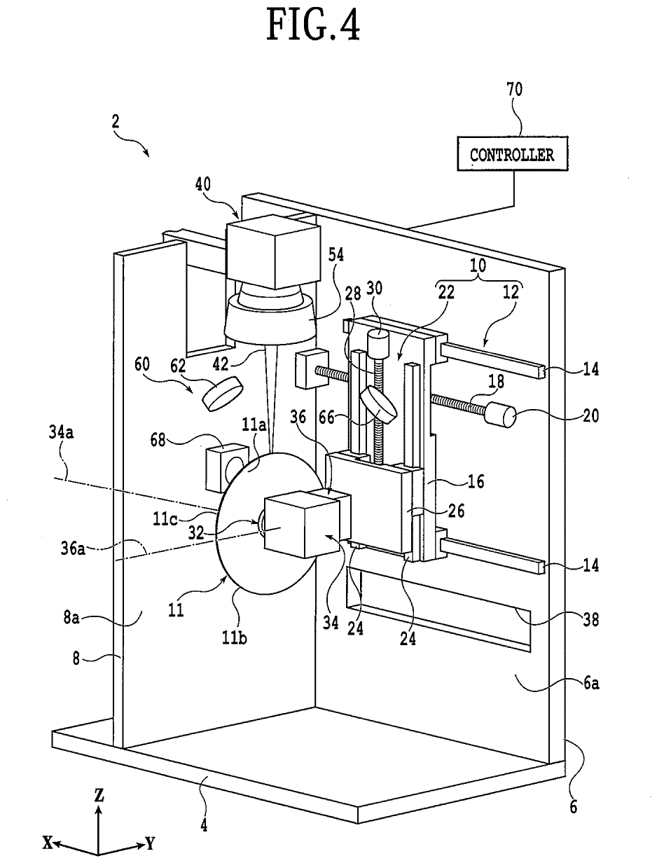

FIG. 4 is a perspective view depicting the laser processing apparatus 2 which holds the workpiece 11 in the vertical direction. When the second rotation mechanism 36 adjusts the orientation of the holding unit 32 (the rotation angle about the second rotational axis 36a) in such a manner that the holding surface 32a (see FIG. 6 and the like) is substantially parallel to the vertical surface (YZ plane), the workpiece 11 is held along the vertical surface, and the side surface 11c side of the workpiece 11 faces the beam condenser 54 of the laser beam applying unit 40. This makes it possible to perform laser processing of applying the laser beam 42 to the workpiece 11 from the side surface 11c side thereof.

Note that the laser processing apparatus 2 may include, in addition to or in place of the second rotation mechanism 36, a rotation mechanism (not illustrated) which rotates the beam condenser 54. This rotation mechanism has a configuration similar to that of the second rotation mechanism 36, and allows the beam condenser 54 to rotate in both directions, with the second rotational axis crossing a direction parallel to the first rotational axis 34a as its center. In addition, the beam condenser 54 may be coupled with a position adjusting unit (not illustrated) for moving the beam condenser 54. This position adjusting unit can have a configuration similar to that of the position adjusting unit 10, for example.

Next, a specific example of a laser processing method of subjecting the workpiece 11 to laser processing with use of the laser processing apparatus 2 described above will be described. In the following description, as a representative example, a mode in which the laser processing apparatus 2 performs chamfering processing and processing of forming the mark 13 on the workpiece 11 is described.

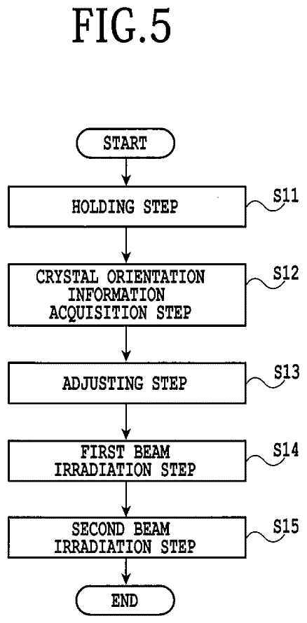

FIG. 5 is a flowchart indicating the laser processing method according to the present embodiment. In the laser processing method indicated in FIG. 5, in a state in which the beam condenser 54 of the laser beam applying unit 40 faces the side surface 11c of the workpiece 11, the laser beam 42 is applied to the workpiece 11, and chamfering processing and processing of forming the mark 13 are performed on the workpiece 11.

Specifically, first, the workpiece 11 is held on the holding surface 32a of the holding unit 32 (holding step S11). FIG. 6 is a front view depicting the laser processing apparatus 2 and the workpiece 11 in the holding step S11.

In the holding step S11, the controller 70 (see FIG. 2) controls the second rotation mechanism 36 (see FIG. 2) to adjust the orientation of the holding unit 32 in such a manner that the holding surface 32a faces downward and is substantially parallel to the horizontal surface (XY plane). Next, the workpiece 11 is transferred by the transfer unit (not illustrated) and is so positioned as to come into contact with the holding surface 32a of the holding unit 32. For example, the workpiece 11 is disposed such that the first surface 11a side faces the holding surface 32a and the second surface 11b side is exposed downward. At this time, the position of the workpiece 11 is adjusted in such a manner that the center position of the workpiece 11 and the center position of the holding surface 32a coincide with each other. In this state, a suction force (negative pressure) of the suction source is applied to the holding surface 32a, and the workpiece 11 is held under suction on the holding unit 32.

As described above, when the workpiece 11 is held on the holding unit 32, the workpiece 11 is disposed concentrically with the holding surface 32a and substantially parallel to the horizontal surface (XY plane). In addition, the diameter of the holding surface 32a of the holding unit 32 is smaller than the diameter of the workpiece 11. Consequently, when the workpiece 11 is held on the holding unit 32, the outer peripheral portion of the workpiece 11 is exposed outside the holding surface 32a.

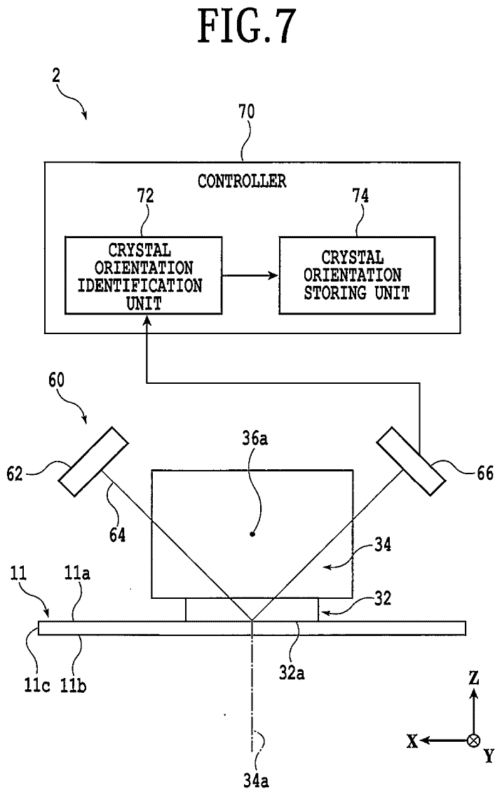

Next, crystal orientation information for identifying the crystal orientation of the workpiece 11 is acquired (crystal orientation information acquisition step S12). FIG. 7 is a front view depicting the laser processing apparatus 2 and the workpiece 11 in the crystal orientation information acquisition step S12.

In the crystal orientation information acquisition step S12, the controller 70 outputs a control signal to the crystal orientation information acquisition unit 60, and the crystal orientation information acquisition unit 60 is actuated. Accordingly, the crystal orientation information of the workpiece 11 is acquired by the crystal orientation information acquisition unit 60.

For example, in a case in which the crystal orientation information acquisition unit 60 is an XRD apparatus including the X-ray irradiator 62 and the detector 66, the X-ray irradiator 62 and the detector 66 are actuated, and the X-rays 64 are applied from the X-ray irradiator 62 to the workpiece 11. After the X-rays 64 applied to the workpiece 11 are diffracted according to the crystal structure of the workpiece 11, they reach the detector 66. Then, the detector 66 receives the X-rays 64, measures the diffraction pattern of the X-rays 64, and outputs the diffraction pattern of the X-rays 64 to the controller 70. Note that the measurement of the diffraction pattern may be carried out multiple times while the workpiece 11 is rotated about the first rotational axis 34a by a predetermined angle each time.

The controller 70 includes a crystal orientation identification unit 72, which identifies the crystal orientation of the workpiece 11, and a crystal orientation storing unit 74, which stores the crystal orientation of the workpiece 11. The crystal orientation identification unit 72 identifies the crystal orientation of the workpiece 11 according to the diffraction pattern of the X-rays 64 measured by the detector 66. Further, the crystal orientation of the workpiece 11 identified by the crystal orientation identification unit 72 is stored in the crystal orientation storing unit 74. For example, the diffraction pattern of the X-rays 64 from the detector 66 and the rotation angle of the holding unit 32 and the workpiece 11 about the first rotational axis 34a from the first rotation mechanism 34 are input to the crystal orientation identification unit 72. Further, the crystal orientation identification unit 72 identifies the direction of a predetermined crystal orientation of the workpiece 11 in a state in which the rotation angle of the workpiece 11 is set to a predetermined value. Thereafter, the crystal orientation identification unit 72 stores the identified direction of the crystal orientation in the crystal orientation storing unit 74 in association with the rotation angle of the workpiece 11.

However, the crystal orientation information acquisition unit 60 may have a function of identifying the crystal orientation of the workpiece 11. In this case, the crystal orientation identification unit 72 may store the information regarding the crystal orientation of the workpiece 11 input from the crystal orientation information acquisition unit 60 without any change, in the crystal orientation storing unit 74.

Note that the timing of acquiring the crystal orientation information of the workpiece 11 is not limited to the case described above, and the crystal orientation information acquisition step S12 can also be performed before the holding step S11. For example, before the workpiece 11 is held on the holding unit 32, in a state in which the workpiece 11 is held by the transfer unit or another holding table, the crystal orientation information of the workpiece 11 may be acquired by the crystal orientation information acquisition unit 60. In this case, according to the position at which the workpiece 11 is to be held, the position where the crystal orientation information acquisition unit 60 is to be provided is selected.

In addition, a method of acquiring the crystal orientation information in the crystal orientation information acquisition step S12 is not limited to XRD. For example, as described above, when the workpiece 11 is processed by the laser beam 42 on trial, cracks of which the development direction depends on the crystal orientation of the workpiece 11 occur. In view of this, the imaging unit (camera) is used as the crystal orientation information acquisition unit 60, and may capture an image of the workpiece 11 which has been subjected to the trial processing. In this case, the image of the workpiece 11 formed with the cracks is acquired as the crystal orientation information. Further, the crystal orientation identification unit 72 identifies the crystal orientation of the workpiece 11 according to the development direction of the cracks indicated in the image.

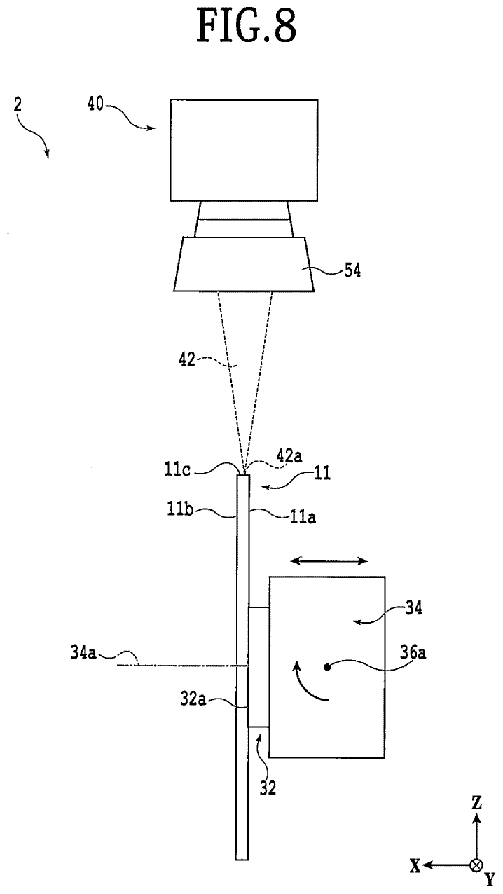

Next, a relative position and orientation between the holding unit 32 and the beam condenser 54 are adjusted in such a manner that the beam condenser 54 faces the side surface 11c of the workpiece 11 (adjusting step S13). FIG. 8 is a front view depicting the laser processing apparatus 2 and the workpiece 11 in the adjusting step S13.

In the adjusting step S13, first, the controller 70 controls the second rotation mechanism 36 (see FIG. 4), and rotates the holding unit 32 about the second rotational axis 36a. For example, in such a manner that the holding surface 32a faces sideways (the left side in FIG. 8), the holding unit 32 is rotated 90° clockwise. In this manner, the holding surface 32a is disposed to be substantially parallel to the YZ plane, and the first surface 11a and the second surface 11b of the workpiece 11 are also disposed to be substantially parallel to the YZ plane.

Next, the controller 70 controls the position adjusting unit 10 (see FIG. 4), and causes the holding unit 32 to move along the X-axis direction and the Z-axis direction. In this manner, for example, the workpiece 11 is positioned directly below the beam condenser 54. As a result, the side surface 11c of the workpiece 11 faces the beam condenser 54, and the laser beam 42 can be applied from the side surface 11c side of the workpiece 11. Note that, as described above, the beam condenser 54 may be coupled with the position adjusting unit (not illustrated) for moving the beam condenser 54. In this case, the beam condenser 54 may be moved by the position adjusting unit to face the side surface 11c of the workpiece 11.

However, in the adjusting step S13, the workpiece 11 is not necessarily required to be positioned directly below the beam condenser 54. More specifically, the position of the focused spot 42a of the laser beam 42 can be adjusted also by the position adjusting unit 50 included in the laser beam applying unit 40 (see FIG. 3). Accordingly, even in a case in which the workpiece 11 is not disposed directly below the beam condenser 54, the position adjusting unit 50 adjusts the position of the focused spot 42a of the laser beam 42, so that the laser beam 42 can be applied to the side surface 11c of the workpiece 11.

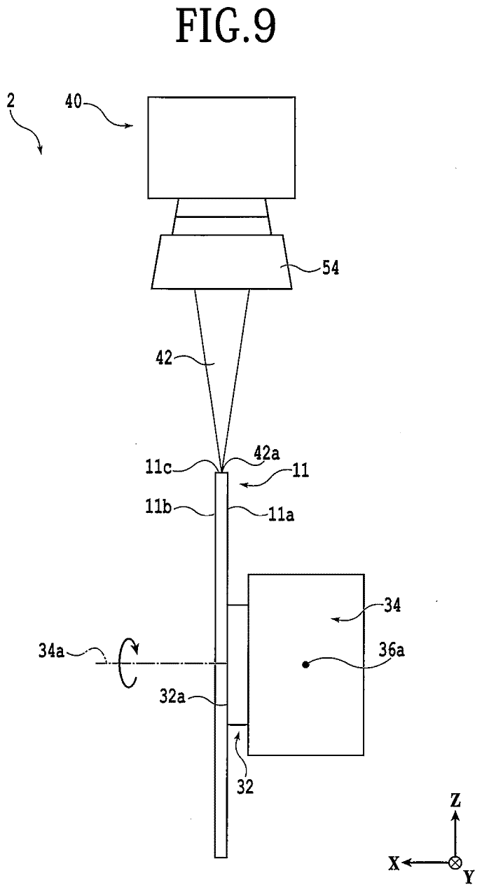

Next, while the laser beam 42 is applied to the workpiece 11 from the beam condenser 54 facing the side surface 11c of the workpiece 11, the holding unit 32 is rotated with the first rotational axis 34a as the center, and the outer peripheral portion of the workpiece 11 is processed into a predetermined shape (first beam irradiation step S14). FIG. 9 is a front view depicting the laser processing apparatus 2 and the workpiece 11 in the first beam irradiation step S14.

In the first beam irradiation step S14, first, the position of the focused spot 42a of the laser beam 42 relative to the workpiece 11 is adjusted. Specifically, the controller 70 controls the position adjusting unit 10 (see FIG. 4) to move the holding unit 32 along the X-axis direction and the Z-axis direction and thereby make a minor adjustment to the position of the workpiece 11. In addition, the controller 70 controls the position adjusting unit 50 (see FIG. 3) to make a minor adjustment to the position of the focused spot 42a of the laser beam 42. Accordingly, the focused spot 42a of the laser beam 42 is positioned at the outer peripheral portion of the workpiece 11 or in the vicinity thereof. However, in a case in which the focused spot 42a of the laser beam 42 has already been positioned at a desired position by performing the adjusting step S13 described above, the adjustment work described above can be omitted. In addition, in the first beam irradiation step S14, the second rotation mechanism 36 (see FIG. 4) may rotate the holding unit 32 to make a minor adjustment to the orientation of the workpiece 11.

Thereafter, the controller 70 controls the first rotation mechanism 34 and the laser beam applying unit 40, and accordingly, the laser beam 42 is applied from the beam condenser 54 to the workpiece 11 while the holding unit 32 and the workpiece 11 are rotated about the first rotational axis 34a. As a result, the laser beam 42 scans the workpiece 11 in a ring shape along the outer peripheral portion of the workpiece 11, and accordingly, the outer peripheral portion of the workpiece 11 is processed into a predetermined shape.

Owing to the processes described above, the workpiece 11 is subjected to chamfering processing. For example, first, in a state in which the focused spot 42a of the laser beam 42 is positioned on the first surface 11a side of the outer peripheral portion of the workpiece 11, the laser beam 42 is applied to the workpiece 11 from the side surface 11c side of the workpiece 11 while the workpiece 11 is rotated. Accordingly, the laser beam 42 is applied to a region on the first surface 11a side of the outer peripheral portion of the workpiece 11, and further, a connection region of the first surface 11a and the side surface 11c is removed. As a result, the corner portion formed by the first surface 11a and the side surface 11c is removed. Next, in a state in which the focused spot 42a of the laser beam 42 is positioned on the second surface 11b side of the outer peripheral portion of the workpiece 11, the laser beam 42 is applied to the workpiece 11 from the side surface 11c side of the workpiece 11 while the workpiece 11 is rotated. Accordingly, the laser beam 42 is applied to a region on the second surface 11b side of the outer peripheral portion of the workpiece 11, and further, the connection region of the second surface 11b and the side surface 11c is removed. As a result, the corner portion formed by the second surface 11b and the side surface 11c is removed.

An irradiation processing condition of the laser beam 42 applied to the workpiece 11 in the first beam irradiation step S14 is appropriately set such that the workpiece 11 is subjected to desired chamfering processing. For example, in the first beam irradiation step S14, the outer peripheral portion of the workpiece 11 is subjected to ablation processing, so that chamfering processing is performed thereon. In this case, a wavelength of the laser beam 42 is set such that at least part of the laser beam 42 is absorbed by the workpiece 11. In other words, the laser beam 42 has absorbability to the workpiece 11. In addition, another irradiation processing condition of the laser beam 42 is also appropriately set such that the workpiece 11 is subjected to appropriate ablation processing. For example, in a case in which the workpiece 11 is a single-crystal silicon wafer, the irradiation processing condition of the laser beam 42 can be set as follows.
Wavelength: 355 nm
Average power: 2 W
Repetition frequency: 50 kHz

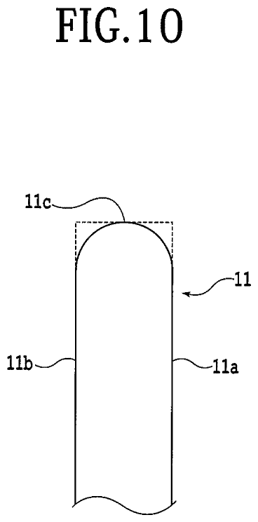

FIG. 10 is a front view depicting the outer peripheral portion of the workpiece 11 subjected to the chamfering processing. When the workpiece 11 has undergone the chamfering processing, the corner portions present at the connection portions of each of the first surface 11a and the second surface 11b and the side surface 11c of the workpiece 11 are removed, and, for example, the side surface 11c is shaped into a curved shape (arc shape) rounded from the first surface 11a to the second surface 11b. As a result, the side surface 11c becomes curved in the radially outward direction of the workpiece 11 (R-chamfering). However, the details of the chamfering processing are not limited to any particular ones. For example, by changing the irradiation processing condition of the laser beam 42 as appropriate, C-chamfering processing or narrow chamfering processing may be performed.

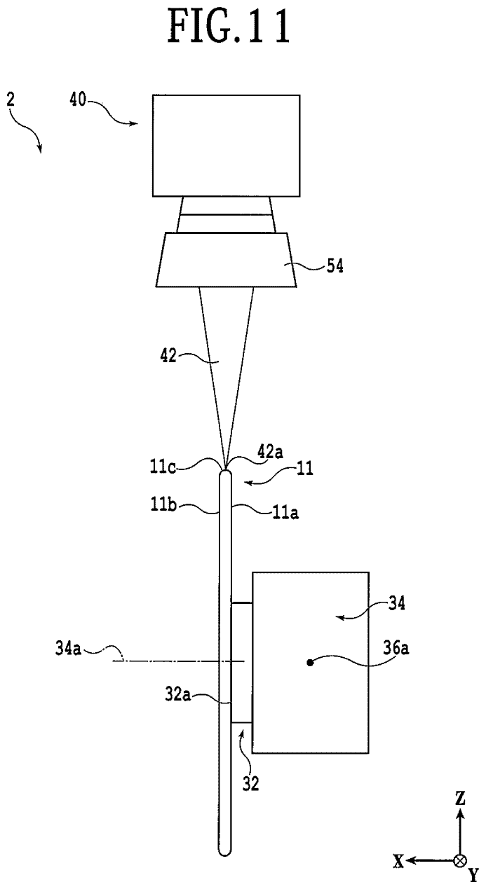

Next, by applying the laser beam 42 to the workpiece 11 from the beam condenser 54 that is caused to face the side surface 11c of the workpiece 11, the mark 13 indicating the crystal orientation of the workpiece 11 is formed in the workpiece 11 (second beam irradiation step S15). FIG. 11 is a front view depicting the laser processing apparatus 2 and the workpiece 11 in the second beam irradiation step S15.

In the second beam irradiation step S15, first, according to the crystal orientation of the workpiece 11 identified by the crystal orientation information acquired in the crystal orientation information acquisition step S12, the position of the focused spot 42a of the laser beam 42 relative to the workpiece 11 is adjusted. Specifically, the controller 70 reads out the information regarding the crystal orientation of the workpiece 11 stored in the crystal orientation storing unit 74 (see FIG. 7). Then, the controller 70 controls the first rotation mechanism 34 to rotate the holding unit 32 and the workpiece 11 about the first rotational axis 34a, and accordingly, the rotation angle of the workpiece 11 is adjusted in such a manner that the predetermined crystal orientation of the workpiece 11 faces a predetermined direction. In FIG. 11, the rotation angle of the workpiece 11 is set in such a manner that the predetermined crystal orientation of the workpiece 11 detected in the crystal orientation information acquisition step S12 is substantially parallel to the Z-axis direction.

Next, the controller 70 controls the laser beam applying unit 40 to apply the laser beam 42 to the workpiece 11 from the beam condenser 54. Accordingly, the laser beam 42 is applied to the workpiece 11 from the side surface 11c side, and the outer peripheral portion of the workpiece 11 is processed. As a result, the mark 13 is formed in the outer peripheral portion of the workpiece 11.

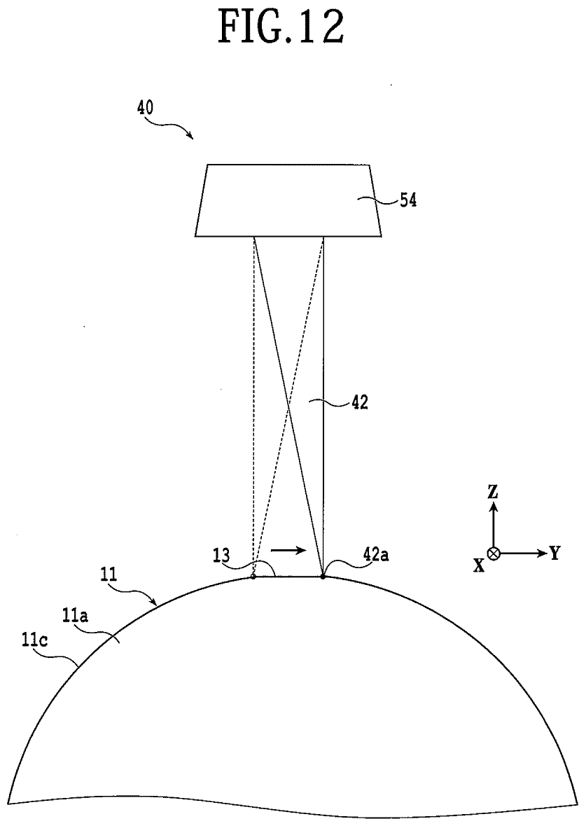

FIG. 12 is a side view depicting the workpiece 11 and the laser beam 42 in the second beam irradiation step S15. For example, in the second beam irradiation step S15, while the laser beam 42 is applied from the beam condenser 54 to the first surface 11a side of the side surface 11c of the workpiece 11, the focused spot 42a is moved along the Y-axis direction. Accordingly, the laser beam 42 scans the workpiece 11 along the Y-axis direction, and the first surface 11a side of the side surface 11c of the workpiece 11 is processed and removed along the Y-axis direction. Subsequently, the focused spot 42a of the laser beam 42 is moved by a predetermined amount along the thickness direction (X-axis direction) of the workpiece 11 and is made closer to the second surface 11b. Then, the laser beam 42 scans the workpiece 11 along the Y-axis direction again. Accordingly, while the position of the focused spot 42a in the thickness direction of the workpiece 11 is changed, the laser beam 42 scans the workpiece 11 multiple times, and the outer peripheral portion of the workpiece 11 is gradually processed and removed from the first surface 11a side to the second surface 11b side thereof. As a result, part of the side surface 11c of the workpiece 11 is processed into a plane substantially vertical to the first surface 11a and the second surface 11b. This plane functions as the mark 13 (mirror surface) indicating the crystal orientation of the workpiece 11. For example, the mark 13 is formed in such a manner that a straight line connecting the center of the workpiece 11 and the mark 13 becomes parallel to or vertical to the predetermined crystal orientation of the workpiece 11.

It is possible to control the position of the focused spot 42a of the laser beam 42 when the workpiece 11 is processed with the laser beam 42, by the position adjusting unit 50 (see FIG. 3). For example, the position adjusting unit 50 includes a galvanoscanner. Accordingly, the focused spot 42a is moved along the Y-axis direction with the galvanoscanner, so that the laser beam 42 scans the workpiece 11 along the Y-axis direction. In addition, the focused spot 42a is moved in the X-axis direction with the galvanoscanner, so that the position of the focused spot 42a in the thickness direction of the workpiece 11 is adjusted. However, the positional relation between the workpiece 11 and the focused spot 42a in the second beam irradiation step S15 can also be controlled by the position adjusting unit 10 or the second rotation mechanism 36 (see FIG. 2 or the like). For example, the position adjusting unit 10 moves the holding unit 32 along with the workpiece 11 in the X-axis direction, and accordingly, the position of the workpiece 11 in the thickness direction relative to the focused spot 42a may be set.

In addition, in the second beam irradiation step S26, as needed, the workpiece 11 and the focused spot 42a may be moved relative to each other along the radial direction (Z-axis direction) of the workpiece 11 by the position adjusting unit 10, the second rotation mechanism 36, or the position adjusting unit 50. Specifically, after the laser beam 42 scans the workpiece 11 at the outer peripheral edge of the workpiece 11 along the Y-axis direction, the focused spot 42a of the laser beam 42 is moved by a predetermined amount in the radial direction (Z-axis direction) of the workpiece 11 toward the center of the workpiece 11, and the laser beam 42 scans the workpiece 11 along the Y-axis direction again. In this manner, while the position of the focused spot 42a in the radial direction of the workpiece 11 is changed, the laser beam 42 scans the workpiece 11 multiple times, and accordingly, the outer peripheral portion of the workpiece 11 is gradually processed and removed from the outer peripheral edge toward the center thereof.

The irradiation processing condition of the laser beam 42 in the second beam irradiation step S15 is set such that the desired mark 13 is suitably formed in the workpiece 11. For example, the irradiation processing condition of the laser beam 42 in the second beam irradiation step S15 can be set as that in the first beam irradiation step S14.

Note that, in FIG. 12, although a case in which the planar mark 13 is formed at the outer peripheral portion of the workpiece 11 has been described, the form of the mark 13 is not limited to this. For example, by application of the laser beam 42, the outer peripheral portion of the workpiece 11 may be formed with the notch or the orientation flat. In addition, by application of the laser beam 42, part of the outer peripheral portion of the workpiece 11 is discolored, and the discolored region can also be used as the mark 13.

In addition, in the description above, although a case in which the second beam irradiation step S15 is performed after the first beam irradiation step S14 has been described, the first beam irradiation step S14 may be performed after the second beam irradiation step S15. However, when the process of forming the mark 13 in the second beam irradiation step S15 after the chamfering processing is performed on the workpiece 11 in the first beam irradiation step S14 is adopted, it is possible to prevent the chamfering processing from being performed after the formation of the mark 13. Accordingly, collapsing of the shape of the mark 13 by the chamfering processing is prevented. In addition, since such chamfering processing as to avoid the mark 13 is not needed, the complicated control for the laser processing apparatus 2 at a time of the chamfering processing becomes unnecessary.

After the second beam irradiation step S15, a test step of testing the mark 13 formed in the workpiece 11 may be performed. For example, in the test step, whether or not the mark 13 suitably functions as the mirror surface is tested. Specifically, check of the angle of the mark 13 relative to the first surface 11a or the second surface 11b of the workpiece 11, check of the reflection direction of light applied to the mark 13, and the like are performed.

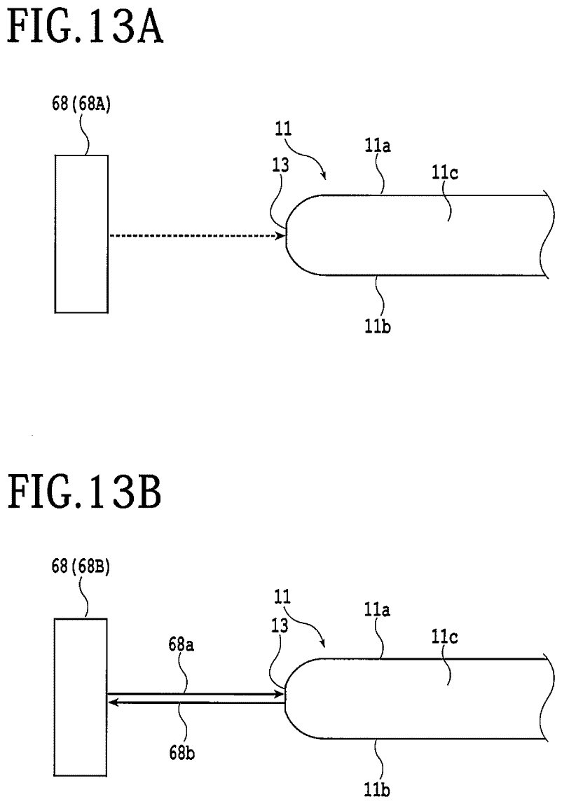

FIG. 13A is a front view depicting part of the workpiece 11 and the workpiece information acquisition unit 68 when the angle of the mark 13 is checked. For example, the laser processing apparatus 2 has an imaging unit (camera) 68A as the workpiece information acquisition unit 68 provided therein. The imaging unit 68A includes an image sensor such as a charged-coupled device (CCD) sensor or a complementary metal-oxide-semiconductor (CMOS) sensor, to capture an image of the workpiece 11 held on the holding unit 32.

After the second beam irradiation step S15, the controller 70 controls the position adjusting unit 10, and the mark 13 formed in the workpiece 11 is positioned to face the imaging unit 68A (see FIG. 2). Subsequently, the imaging unit 68A images the mark 13 and acquires the image of the mark 13. Then, for example, the operator visually recognizes the image of the mark 13, and checks whether or not the mark 13 is formed at an appropriate angle. In addition, the operator may check not only the angle of the mark 13, but also the position of the mark 13, as well as the suitability of the size or the like.

Note that a determination as to whether or not the mark 13 is suitable may be carried out automatically by the controller 70 on the basis of the image of the mark 13. The image of the mark 13 acquired by the imaging unit 68A is input to the controller 70 (see FIG. 2). Further, the controller 70 calculates the angle, the position, and the size of the mark 13, or the like, by performing image processing on the image of the mark 13, and determines whether or not the mark 13 is suitable.

FIG. 13B is a front view depicting part of the workpiece 11 and the workpiece information acquisition unit 68 when the reflection direction of light applied to the mark 13 is checked. In the laser processing apparatus 2, an optical sensor 68B may be provided as the workpiece information acquisition unit 68. For example, the optical sensor 68B is a reflective-type optical sensor, and includes a light source which applies detection light 68a to the workpiece 11 and a light detector which receives reflection light 68b from the workpiece 11.

In a case in which the mark 13 formed in the workpiece 11 is the abovementioned mirror surface (flat plane), whether or not the mark 13 is suitably formed can be tested by the optical sensor 68B. Specifically, after the second beam irradiation step S15, the controller 70 controls the position adjusting unit 10, and the mark 13 formed in the workpiece 11 is positioned to face the optical sensor 68B (see FIG. 2). After that, the detection light 68a is applied from the optical sensor 68B to the mark 13, and the detection light 68a reflected by the mark 13 is received as reflection light 68b by the optical sensor 68B. Accordingly, the optical sensor 68B measures an intensity (light receiving amount) of the received reflection light 68b.

In a case in which the mark 13 is suitably formed in the workpiece 11, the mark 13 becomes a flat plane, and is disposed to be substantially parallel to the thickness direction of the workpiece 11 (substantially vertical to the first surface 11a and the second surface 11b). In this case, the detection light 68a is more likely to be reflected toward the optical sensor 68B, and a received light amount of the reflection light 68b received by the optical sensor 68B increases. In contrast, in a case in which formation of the mark 13 is not appropriate, the mark 13 may be inclined relative to the thickness direction of the workpiece 11 or the surface of the mark 13 may become rough. In this case, misalignment between a light incident direction and the reflection direction of the detection light 68a or diffusion of the detection light 68a at the mark 13 may be more likely to occur, and accordingly, the received light amount of the reflection light 68b received by the optical sensor 68B decreases. Hence, according to the received light amount of the optical sensor 68B, the reflection direction of the detection light 68a is checked, making it possible to determine whether or not the mark 13 is appropriately formed. For example, the received light amount of the optical sensor 68B is input to the controller 70 (see FIG. 2). In addition, in the controller 70, a reference value (threshold value) of the received light amount is stored in advance. The controller 70 compares the received light amount of the optical sensor 68B with the reference value, and determines whether or not the mark 13 is appropriately formed.

The holding step S11 to the second beam irradiation step S15 (and the test step) are implemented by executing a program stored in the controller 7. Specifically, in the storing unit of the controller 70, a program in which processing for activating the components of the laser processing apparatus 2 is described in order to execute the steps described above is stored. The controller 70 reads out the program above and executes it, and accordingly, the holding step S11 to the second beam irradiation step S15 (and test step) are automatically carried out.

As described above, according to the laser processing apparatus 2 and the laser processing method of the present embodiment, the controller 70 controls the position adjusting unit 10, the first rotation mechanism 34, and the second rotation mechanism 36, so that the beam condenser 54 facing the side surface 11c of the workpiece 11 can apply the laser beam 42 to the workpiece 11. Accordingly, with use of the same laser processing apparatus 2, chamfering processing and processing of forming the mark 13 can sequentially be performed on the workpiece 11, making it possible to simplify processing of the workpiece 11 and lower the cost.

Note that, in the present embodiment, an example in which the workpiece 11 is subjected to the chamfering processing in the first beam irradiation step S14 has been described (see FIG. 9 and FIG. 10), but in the first beam irradiation step S14, the workpiece 11 can be subjected to processing other than the chamfering processing. For example, in a state in which the workpiece 11 is held in a horizontal direction, the laser beam 42 is applied to the workpiece 11 (see FIG. 2), so that processing of removing the outer peripheral portion of the workpiece 11, processing of forming the laser processing grooves at the outer peripheral portion of the workpiece 11, or the like, can also be performed.

Besides, a structure, a method, and the like according to the above embodiment may appropriately be modified, and various modifications can be implemented without departing from the scope of object of the present invention. In addition, the configurations, the methods, and the like according to the present embodiment may appropriately be combined with those of other embodiments.

### Second Embodiment

In the first embodiment, an example in which, after the side surface 11c of the workpiece 11 faces the beam condenser 54 (see FIG. 8) in the adjusting step S13, the laser beam 42 is applied from the side surface 11c of the workpiece 11 to perform the chamfering processing (see FIG. 9) and processing of forming the mark 13 (see FIG. 11) on the workpiece 11 has been described. However, the laser processing apparatus 2 can apply the laser beam 42 to the workpiece 11 from different directions and thereby perform processing of forming the mark 13 and other processing on the workpiece 11 as well.

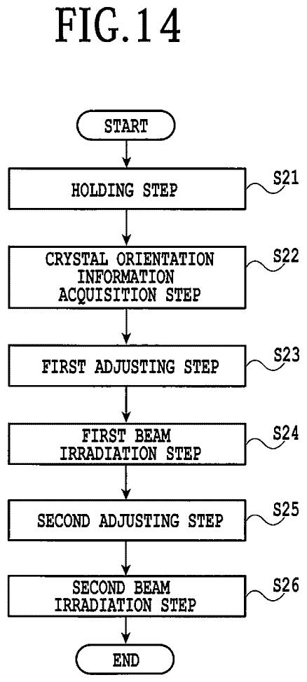

FIG. 14 is a flowchart indicating a modification example of the laser processing method. In the laser processing method indicated in FIG. 14, after chamfering processing is applied to the workpiece 11 by application of the laser beam 42 from the beam condenser 54 that is caused to face the side surface 11c of the workpiece 11, the laser beam 42 is applied from the beam condenser 54 that is caused to face the first surface 11a or the second surface 11b of the workpiece 11, to form the mark 13 in the workpiece 11. Note that the configurations and the functions of the laser processing apparatus 2, the details of the laser processing method, and the like according to the present embodiment are the same as those of the first embodiment, except for the matters described below.

In the present embodiment, first, a holding step S21, a crystal orientation information acquisition step S22, a first adjusting step S23, and a first beam irradiation step S24 are performed in this order. The details of the holding step S21, the crystal orientation information acquisition step S22, the first adjusting step S23, and the first beam irradiation step S24 are the same as those in the holding step S11, the crystal orientation information acquisition step S12, the adjusting step S13, and the first beam irradiation step S14 in the first embodiment. More specifically, the workpiece 11 is held on the holding unit 32 in the holding step S21 (see FIG. 6), the information regarding the crystal orientation of the workpiece 11 is acquired in the crystal orientation information acquisition step S22 (see FIG. 7), and the workpiece 11 is subjected to the chamfering processing in the first adjusting step S23 and the first beam irradiation step S24 (see FIG. 8 and FIG. 9).

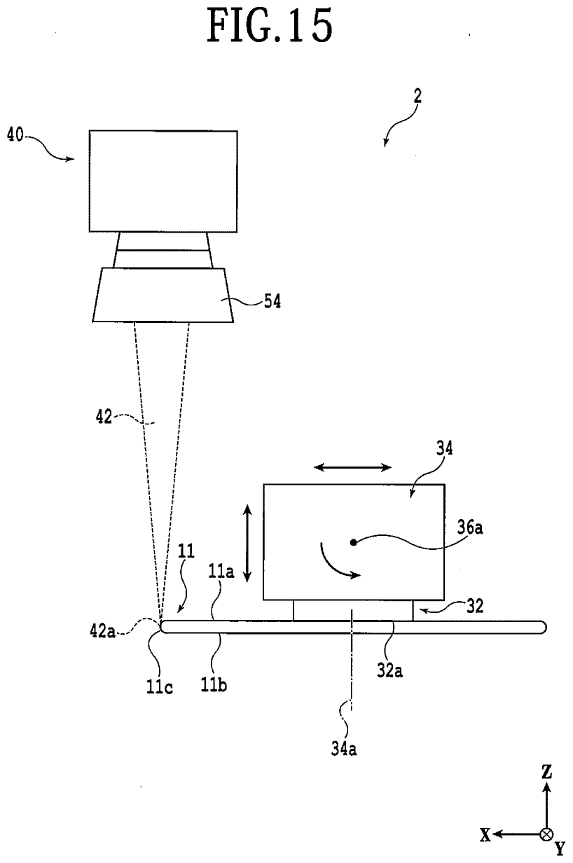

Then, after the first beam irradiation step S24, in such a manner that the beam condenser 54 faces the first surface 11a or the second surface 11b of the workpiece 11, a relative position and orientation between the holding unit 32 and the beam condenser 54 is adjusted (second adjusting step S25). FIG. 15 is a front view depicting the laser processing apparatus 2 and the workpiece 11 in the second adjusting step S25.

In the second adjusting step S25, first, the controller 70 controls the second rotation mechanism 36 (see FIG. 2), to rotate the holding unit 32 around the second rotational axis 36a. For example, in such a manner that the holding surface 32a faces downward, the holding unit 32 is rotated 90° in a counterclockwise direction. Accordingly, the holding surface 32a is disposed to be substantially parallel to the XY plane, and the first surface 11a and the second surface 11b of the workpiece 11 are also disposed to be substantially parallel to the XY plane.

Next, the controller 70 controls the position adjusting unit 10 (see FIG. 2), and moves the holding unit 32 along the X-axis direction and the Z-axis direction. Accordingly, the outer peripheral portion of the workpiece 11 is positioned immediately below the beam condenser 54. As a result, the first surface 11a of the workpiece 11 faces the beam condenser 54, and application of the laser beam 42 from the first surface 11a side of the workpiece 11 is achieved.

However, in the second adjusting step S25, it is not necessarily required to position the outer peripheral portion of the workpiece 11 immediately below the beam condenser 54. More specifically, the position of the focused spot 42a of the laser beam 42 can be adjusted also by the position adjusting unit 50 included in the laser beam applying unit 40 (see FIG. 3). Accordingly, even in a case in which the outer peripheral portion of the workpiece 11 is not disposed immediately below the beam condenser 54, the position of the focused spot 42a of the laser beam 42 is adjusted by the position adjusting unit 50, so that the laser beam 42 can be applied to the outer peripheral portion of the workpiece 11. In addition, in the second adjusting step S25, the second surface 11b of the workpiece 11 may face the beam condenser 54. In this case, in such a manner that the holding surface 32a faces upward, the holding unit 32 may be rotated 90° in the clockwise direction.

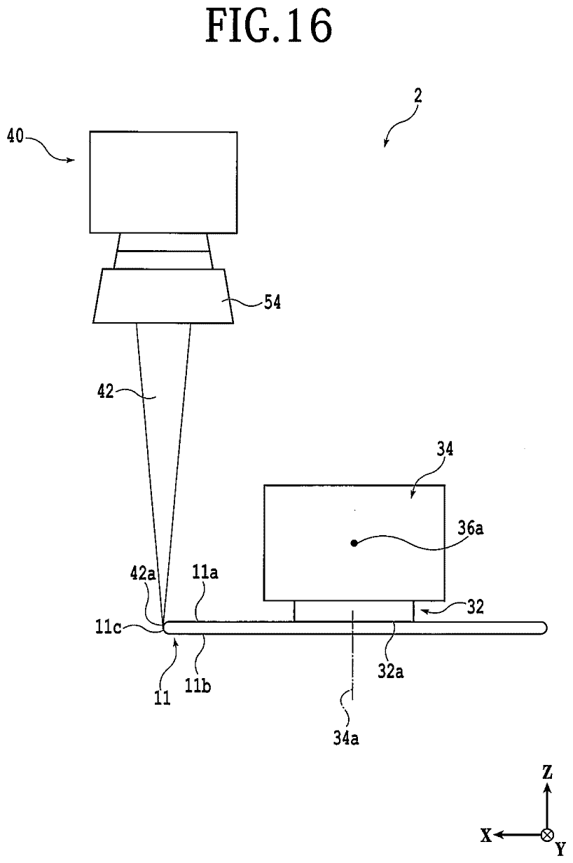

Next, the laser beam 42 is applied to the workpiece 11 from the beam condenser 54 that is caused to face the first surface 11a or the second surface 11b of the workpiece 11, so that the mark 13 indicating the crystal orientation of the workpiece 11 is formed in the workpiece 11 (second beam irradiation step S26). FIG. 16 is a front view depicting the laser processing apparatus 2 and the workpiece 11 in the second beam irradiation step S26.

In the second beam irradiation step S26, first, according to the crystal orientation of the workpiece 11 identified by the crystal orientation information acquired in the crystal orientation information acquisition step S22, the position of the focused spot 42a of the laser beam 42 relative to the workpiece 11 is adjusted. Specifically, the controller 70 reads out the information regarding the crystal orientation of the workpiece 11 stored in the crystal orientation storing unit 74 (see FIG. 7). Then, the controller 70 controls the first rotation mechanism 34 to rotate the holding unit 32 and the workpiece 11 around the first rotational axis 34a, and accordingly, the rotation angle of the workpiece 11 is adjusted in such a manner that the predetermined crystal orientation of the workpiece 11 faces a predetermined direction. In FIG. 16, the rotation angle of the workpiece 11 is set in such a manner that the predetermined crystal orientation of the workpiece 11 detected in the crystal orientation information acquisition step S22 becomes substantially parallel to the X-axis direction.

Next, the controller 70 controls the laser beam applying unit 40, causing the beam condenser 54 to apply the laser beam 42 to the workpiece 11. As a result, the laser beam 42 is applied to the workpiece 11 from the first surface 11a side, and the outer peripheral portion of the workpiece 11 is processed. Consequently, the mark 13 is formed at the outer peripheral portion of the workpiece 11.

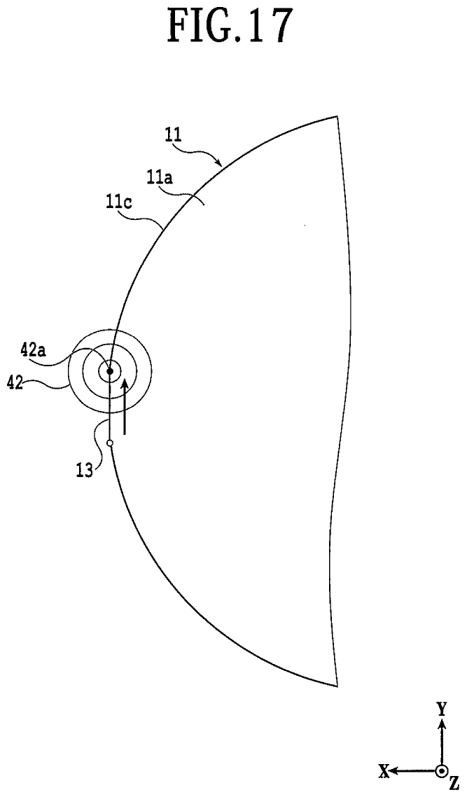

FIG. 17 is a plan view depicting the workpiece 11 and the laser beam 42 in the second beam irradiation step S26. For example, in the second beam irradiation step S26, while the laser beam 42 is applied from the beam condenser 54 to the first surface 11a side of the outer peripheral portion of the workpiece 11, the focused spot 42a is moved along the Y-axis direction. Accordingly, the laser beam 42 scans the workpiece 11 along the Y-axis direction, and the first surface 11a side of the outer peripheral portion of the workpiece 11 is processed and removed along the Y-axis direction.

After that, the focused spot 42a of the laser beam 42 is moved by a predetermined amount along the radial direction of the workpiece 11 (X-axis direction), to be brought closer to the center of the workpiece 11. Then, the laser beam 42 scans the workpiece 11 along the Y-axis direction again. Accordingly, while the position of the focused spot 42a in the radial direction of the workpiece 11 is changed, the laser beam 42 scans the workpiece 11 multiple times, and the outer peripheral portion of the workpiece 11 is gradually processed and removed from the outer peripheral edge to the center of the workpiece 11. As a result, part of the side surface 11c is processed into a plane substantially vertical to the first surface 11a and the second surface 11b. This plane functions as the mark 13 (mirror surface) indicating the crystal orientation of the workpiece 11. For example, the mark 13 is formed such that the straight line connecting the center of the workpiece 11 and the mark 13 becomes parallel or vertical to the predetermined crystal orientation of the workpiece 11.

The position of the focused spot 42a when the laser beam 42 processes the workpiece 11 can be controlled by the position adjusting unit 50 (see FIG. 3). For example, the position adjusting unit 50 includes a galvanoscanner. The galvanoscanner moves the focused spot 42a in the Y-axis direction, and the laser beam 42 scans the workpiece 11 along the Y-axis direction. In addition, the galvanoscanner moves the focused spot 42a in the X-axis direction, so that the position of the focused spot 42a in the radial direction of the workpiece 11 is adjusted.

However, the positional relation between the workpiece 11 and the focused spot 42a in the second beam irradiation step S26 can also be controlled by the position adjusting unit 10 or the second rotation mechanism 36 (see FIG. 2 or the like). For example, the holding unit 32 may be moved together with the workpiece 11 in the X-axis direction by the position adjusting unit 10, and the position of the workpiece 11 in the radial direction relative to the focused spot 42a may thereby be set.

In addition, in the second beam irradiation step S26, as needed, the position adjusting unit 10, the second rotation mechanism 36, or the position adjusting unit 50 may move the workpiece 11 and the focused spot 42a relative to each other along the thickness direction of the workpiece 11 (Z-axis direction). Specifically, in a state in which the focused spot 42a is positioned on the first surface 11a side of the workpiece 11, the laser beam 42 scans the workpiece 11 along the Y-axis direction, and then, the focused spot 42a of the laser beam 42 is moved along the thickness direction of the workpiece 11 (Z-axis direction) to the second surface 11b side by a predetermined amount. Then, the laser beam 42 scans the workpiece 11 along the Y-axis direction again. In this manner, while the position of the focused spot 42a in the thickness direction of the workpiece 11 is changed, the laser beam 42 scans the workpiece 11 multiple times. As a result, the outer peripheral portion of the workpiece 11 is gradually processed and removed from the first surface 11a to the second surface 11b thereof.

The irradiation processing condition of the laser beam 42 in the second beam irradiation step S26 is appropriately set in such a manner that the desired mark 13 is suitably formed in the workpiece 11. For example, the irradiation processing condition of the laser beam 42 in the second beam irradiation step S26 can be set in a manner similar to those of the first beam irradiation steps S14 and S24 or the second beam irradiation step S15.

Note that, in FIG. 17, although a case in which a planar mark 13 is formed at the outer peripheral portion of the workpiece 11 has been described, the form of the mark 13 is not limited to this. For example, by application of the laser beam 42, a notch or an orientation flat may be formed at the outer peripheral portion of the workpiece 11. In addition, the application of the laser beam 42 may discolor part of the outer peripheral portion of the workpiece 11, also allowing the discolored region to be used as the mark 13.

In addition, although a case in which the second adjusting step S25 and the second beam irradiation step S26 are performed after the first adjusting step S23 and the first beam irradiation step S24 has been described above, the first adjusting step S23 and the first beam irradiation step S24 may be performed after the second adjusting step S25 and the second beam irradiation step S26. However, adopting the process of forming the mark 13 in the second adjusting step S25 and the second beam irradiation step S26 after the workpiece 11 is subjected to the chamfering processing through the first adjusting step S23 and the first beam irradiation step S24 makes it possible to avoid performing chamfering processing on the workpiece 11 after the formation of the mark 13, as described above.

After the second beam irradiation step S15, the test step of testing the mark 13 may be performed on the workpiece 11. The specific example of details of the test step is the same as that of the first embodiment.

As described above, according to the laser processing apparatus and the laser processing method of the present embodiment, the controller 70 controls the position adjusting unit 10, the first rotation mechanism 34, and the second rotation mechanism 36, so that the laser beam 42 can be applied to the workpiece 11 from the beam condenser 54 that faces the side surface 11c of the workpiece 11 and that the laser beam 42 can be applied to the workpiece 11 from the beam condenser 54 that faces the first surface 11a or the second surface 11b of the workpiece 11. Hence, the same laser processing apparatus 2 can be used to sequentially perform the chamfering processing and the processing of forming the mark 13 on the workpiece 11, thereby achieving simplified processing of the workpiece 11 and low cost.

Note that, in the present embodiment, although an example in which the chamfering processing is performed on the workpiece 11 in the first beam irradiation step S24 has been described, the workpiece 11 can also be subjected to processing other than the chamfering processing in the first beam irradiation step S24. In this case, the workpiece 11 may be processed in a state of being held in a horizontal direction (see FIG. 2) or in a vertical direction (see FIG. 4).

Besides, a structure, a method, and the like according to the above embodiment may appropriately be modified, and various modifications can be implemented without departing from the scope of the object of the present invention. In addition, the configurations, the methods, and the like according to the present embodiment may appropriately be combined with those of other embodiments.

The present invention is not limited to the details of the above described preferred embodiments. The scope of the invention is defined by the appended claims and all changes and modifications as fall within the equivalence of the scope of the claims are therefore to be embraced by the invention.

What is claimed is:

1. A laser processing apparatus which applies a laser beam to a workpiece having a crystal structure to perform laser processing on the workpiece, comprising:
a holding unit including a holding surface for holding the workpiece having a first surface, a second surface, and a side surface that is connected to the first surface and the second surface;
a laser oscillator which emits the laser beam;
a beam condenser for focusing the laser beam emitted from the laser oscillator;
a position adjusting unit which adjusts a positional relation between the holding unit and a focused spot of the laser beam;
a first rotation mechanism which rotates the holding unit with a first rotational axis crossing the holding surface as a center;
a second rotation mechanism which rotates the holding unit or the beam condenser with a second rotational axis crossing a direction parallel to the first rotational axis as a center;
a crystal orientation information acquisition unit which acquires crystal orientation information for identifying a crystal orientation of the workpiece held on the holding unit; and
a controller,
wherein the controller applies the laser beam to the workpiece from a side of the side surface in a state in which the beam condenser faces the side surface of the workpiece and a position of the focused spot relative to the workpiece is adjusted according to the crystal orientation of the workpiece identified by the crystal orientation information, by controlling the position adjusting unit, the first rotation mechanism, and the second rotation mechanism.

2. A laser processing apparatus which applies a laser beam to a workpiece having a crystal structure to perform laser processing on the workpiece, comprising:
a holding unit including a holding surface for holding the workpiece having a first surface, a second surface, and a side surface that is connected to the first surface and the second surface;
a laser oscillator which emits the laser beam;
a beam condenser for focusing the laser beam emitted from the laser oscillator;
a position adjusting unit which adjusts a positional relation between the holding unit and a focused spot of the laser beam;
a first rotation mechanism which rotates the holding unit with a first rotational axis crossing the holding surface as a center;
a second rotation mechanism which rotates the holding unit or the beam condenser with a second rotational axis crossing a direction parallel to the first rotational axis as a center;
a crystal orientation information acquisition unit which acquires crystal orientation information for identifying a crystal orientation of the workpiece held on the holding unit; and
a controller,
wherein the controller applies the laser beam to the workpiece from a side of the first surface or the second surface in a state in which the beam condenser faces the first surface or the second surface of the workpiece and a position of the focused spot relative to the workpiece is adjusted according to the crystal orientation of the workpiece identified by the crystal orientation information, by controlling the position adjusting unit, the first rotation mechanism, and the second rotation mechanism.

3. The laser processing apparatus according to claim 1,
wherein the controller switches between a state in which the beam condenser faces the side surface of the workpiece and a state in which the beam condenser faces the first surface or the second surface of the workpiece, by controlling the second rotation mechanism.

4. The laser processing apparatus according to claim 1,
wherein the crystal orientation information acquisition unit detects a diffraction pattern detected by X-rays applied to the workpiece.

5. The laser processing apparatus according to claim 1, further comprising:
a workpiece information acquisition unit which acquires one of or both information regarding a shape of the workpiece and information regarding surface characteristics of the workpiece.

6. A laser processing method comprising:
holding a workpiece with a crystal structure having a first surface, a second surface, and a side surface connected to the first surface and the second surface on a holding surface of a holding unit;
acquiring crystal orientation information for identifying a crystal orientation of the workpiece;
adjusting a relative position and orientation between the holding unit and a beam condenser in such a manner that the beam condenser focusing a laser beam faces the side surface of the workpiece held on the holding unit;
processing an outer peripheral portion of the workpiece into a predetermined shape by rotating the holding unit with a rotational axis crossing the holding surface as a center, while the laser beam is being applied to the workpiece held on the holding unit from the beam condenser that is caused to face the side surface of the workpiece; and
forming a mark indicating a crystal orientation of the workpiece in the workpiece by adjusting a position of the focused spot of the laser beam relative to the workpiece, according to the crystal orientation of the workpiece identified by the crystal orientation information, and applying the laser beam to the workpiece held on the holding unit from the beam condenser that is caused to face the side surface of the workpiece.

7. A laser processing method comprising:
holding a workpiece with a crystal structure having a first surface, a second surface, and a side surface connected to the first surface and the second surface on a holding surface of a holding unit;
acquiring crystal orientation information for identifying a crystal orientation of the workpiece;
adjusting a relative position and orientation between the holding unit and a beam condenser in such a manner that the beam condenser focusing a laser beam faces the side surface of the workpiece held on the holding unit;
processing an outer peripheral portion of the workpiece into a predetermined shape by rotating the holding unit with a rotational axis crossing the holding surface as a center, while the laser beam is being applied to the workpiece held on the holding unit from the beam condenser that is caused to face the side surface of the workpiece;
adjusting a relative position and orientation between the holding unit and the beam condenser in such a manner that the beam condenser faces the first surface or the second surface of the workpiece held on the holding unit; and
forming a mark indicating a crystal orientation of the workpiece in the workpiece by adjusting a position of the focused spot of the laser beam relative to the workpiece, according to the crystal orientation of the workpiece identified by the crystal orientation information, and applying the laser beam to the workpiece held on the holding unit from the beam condenser that is caused to face the first surface or the second surface of the workpiece.

8. The laser processing method according to claim 6,
wherein, in the acquiring the crystal orientation information, a diffraction pattern of X-rays applied to the workpiece is detected.

9. The laser processing method according to claim 6,
wherein the mark is a plane formed at the outer peripheral portion of the workpiece, and
one of or both a planar angle relative to the first surface or the second surface of the workpiece and a reflection direction of light applied to the plane is/are checked.
